(19) United States
(12) Patent Application Publication
(10) Pub. No.: US 2015/0211108 A1
(43) Pub. Date: Jul. 30, 2015

(54) SPUTTERING TARGET AND PRODUCING METHOD THEREOF

(71) Applicant: MITSUBISHI MATERIALS CORPORATION, Tokyo (JP)

(72) Inventors: Shoubin Zhang, Sanda-shi (JP); Keita Umemoto, Sanda-shi (JP)

(73) Assignee: MITSUBISHI MATERIALS CORPORATION, Tokyo (JP)

(21) Appl. No.: 14/420,379

(22) PCT Filed: Aug. 8, 2013
(86) PCT No.: PCT/JP2013/071516

§ 371 Date: Feb. 9, 2015

(30) Foreign Application Priority Data
Aug. 10, 2012 (JP) 2012-178888

(51) Int. Cl. C23C 14/34; C22C 30/02; C22C 9/00; C22C 28/00; B22F 3/10; C23C 14/14

(52) U.S. Cl. CPC C23C 14/3414; B22F 3/1007; C23C 14/14; C22C 9/00; C22C 28/00; C22C 30/02

(57) ABSTRACT

The sputtering target has a component composition containing Ga: 2 to 30 at %, In: 15 to 45 at %, Na: 0.05 to 15 at % as metal components other than F, S and Se in the sputtering target and the remainder composed of Cu and inevitable impurities. The sputtering target has a composition in which a Na compound phase is dispersed, the Na is contained in the Na compound phase, a theoretical density ratio of the sintered body is 90% or more, a deflective strength is 60 N/mm² or more, a bulk resistivity is 0.1 Ω*cm or less, and the number of Na compound aggregates having a size of 0.05 mm² or more contained in an area of 1 cm² of a surface of the sputtering target is one or less on average.

### TECHNICAL FIELD

The present invention relates to a sputtering target for use in forming Cu—In—Ga—Se compound film (hereinafter, referred to as “CIGS film”) for forming a light absorbing layer of a thin type solar battery, and a producing method thereof.

Priority is claimed on Japanese Patent Application No. 2012-178888, filed Aug. 10, 2012, the contents of which are incorporated herein by reference.

### BACKGROUND ART

In recent years, thin film solar cells made by using a chalcopyrite compound semiconductor have been practically employed. The thin-film solar cell made by using the compound semiconductor has a basic structure in which an Mo electrode layer serving as a positive electrode is formed on a sodalime glass substrate, a light absorbing layer consisting of a CIGS film is formed on the Mo electrode layer, a buffer layer consisting of ZnS, CdS, and the like is formed on the light absorbing layer, and a transparent electrode layer serving as a negative electrode is formed on the buffer layer.

As a method for forming the light absorbing layer described above, a vapor deposition film-forming method is known. Although a light absorbing layer obtained by the method, may exhibit high energy conversion efficiency, the vapor deposition film-forming method attains slow speed for forming a film. Hence, when a film is formed on a substrate having a large area, the uniformity of the in-plane distribution of the film thickness is readily reduced. Thus, a sputtering method for forming a light absorbing layer has been proposed.

As a method for forming the light absorbing layer described above, a method has been proposed in which a Cu—Ga binary alloy film is firstly formed by sputtering using a Cu—Ga alloy target, an In film is formed on the Cu—Ga (binary alloy) film by sputtering using an In sputtering target, and a stacked precursor film consisting of the obtained Cu—Ga binary alloy film and In film is subjected to heat treatment in a Selenium atmosphere to thereby form a CIGS film (so called “selenization method”). In addition, for example, according to Patent Document 1, a method has been proposed in which a Cu—Ga—In film is formed by sputtering using a Cu—Ga—In alloy target, and then the film is subjected to heat treatment in a Selenium atmosphere so as to thereby form a CIGS film.

In order to improve an electric generation efficiency of the light absorbing layer made of the CIGS film, for example, an addition of Na into the light absorbing layer by the diffusion from an alkaline glass substrate is effective as shown in Non-Patent document 1. However, there is an inconvenience in that in a case of a flexible CIGS solar battery in which a polymer film instead of the alkaline glass substrate is a base material, a supply source of Na is lost because there is no alkaline glass substrate.

Accordingly, for example, the Patent Document 2 has proposed that a lift-off layer by sodium chloride is provided and Na is diffused into the light absorbing layer from the lift-off layer in order to improve photoelectric conversion properties of the flexible CIGS solar battery formed on the polymer film.

With respect to the addition of Na, in Non-Patent Documents 1 and 2, a method has been proposed in which a soda-lime glass is formed between a Mo electrode layer and a substrate. However, when there is the soda-lime glass as in the Non-Patent Documents, the producing processes increase and the productivity is reduced.

Thus, as shown in Patent document 3, a technique has been proposed in which sodium saline is added in a Cu—In—Ga (hereinafter described as “CIG”) precursor film and a supply of Na into the light absorbing layer is secured. Thus, the addition of sodium saline into a metal target of Cu—In—Ga has been considered.

### PRIOR ART DOCUMENTS

### Patent Documents

[Patent Document 1] U.S. Unexamined Patent Application Publication No. 2011/089030 Specification
[Patent Document 2] Japanese Unexamined Patent Application, First Publication No. 2009-49389
[Patent Document 3] U.S. Pat. No. 7,935,558 Specification

### Non-Patent Document

[Non-Patent Document 1] Ishizuka et al., “Current situation of development of Chalcopyrite-based-thin-film-solar battery and future perspective thereof” Journal of the Vacuum Society of Japan, Vol 53, No. 1 2010 p. 25
[Non-Patent Document 2] Ishizuka et al., “Na-induced variations in the structural, optical, and electrical properties of Cu, In, Ga . . . Se₂ thin films”, JOURNAL OF APPLIED PHYSICS 106, 034908_{—}2009
[Non-Patent Document 3] D. Rudmann et al., “Effect of NaF coevaporation on structural properties of Cu(In,Ga)Se₂ thin films”, Thin Solid Films 431-432 (2003)37-40

### DISCLOSURE OF THE INVENTION

### Problems to be Solved by the Invention

Following problems remain in the prior art.

When a sputtering target is produced by the producing method described in Patent Document 3, there has been a problem in that sodium saline, which has non-conductive properties, cannot be mixed properly in a basis metal of CIG sputtering target and a lot of discoloration and spots on a surface of the target occur, and thereby, an abnormal discharge such as hard arc and soft arc easily occur during direct-current (DC) sputtering for mass production and a stable deposition cannot be secured. That is, in the producing method of the Patent Document 3, since Na saline is easily agglomerated and furthermore easily adsorbs moisture, accordingly, discoloration and spots occur on the surface of the sputtering target, and eventually, there is an inconvenience in that the properties of the solar battery produced of this sputtering target is significantly unstable.

In addition, according to a large amount of addition of Na saline, there is an inconvenience in that a frequent abnormal discharge occurs during sputtering, and furthermore, a mechanical strength of the sputtering target is low and the sputtering target is ease to crack. That is, according to a large amount of addition of Na saline which has no conductivity, is difficult to be sintered and is low in mechanical strength, the mechanical strength of the sputtering target lowers, a generation rate of defects during machining increases, and furthermore, abnormal discharge caused by a Na compound occurs easily during sputtering.

The present invention has been made in view of the above problems, and the object thereof is to provide: a sputtering target in which occurrence of discoloration, spots and abnormal discharge is suppressed even though high concentration of Na is contained, and furthermore, which has a high strength and is hard to crack, and the producing method thereof.

### Means for Solving the Problem

The inventors of the present invention have investigated that 0.05 to 15 at. % of Na can be added to a Cu—In—Ga alloy sputtering target having Ga concentration: 2 to 30 at. % and In concentration: 15 to 45 at. %. As the result, the inventors have found that the above problems can be overcome along with an addition of Na to a sputtering target by the selection of a raw material, an improvement of the producing method and the like.

The present invention is obtained by the above findings, and in order to solve the problems, the present invention adopts the following configurations.

(1) A sputtering target according to the present invention is a sintered body having a component composition containing Ga: 2 to 30 at. %, In: 15 to 45 at. %, Na: 0.05 to 15 at. % as metal components other than F, S and Se in the sputtering target, and the remainder composed of Cu and inevitable impurities, wherein the sintered body having a composition in which a Na compound phase is dispersed and the Na is contained in the Na compound phase in a state of a Na compound formed of at least one form of sodium fluoride, sodium sulfide, and sodium selenide, and wherein an average grain size of the Na compound phase is 10 μm or less.

(2) The sputtering target according to (1) may have a theoretical density ratio of the sintered body being 90% or more, a deflective strength being 60 N/mm² or more, a bulk resistivity being 0.1 Ω*cm or less, and the number of Na compound aggregates having a size of 0.05 mm² or more contained in an area of 1 cm² of a surface of the sputtering target being one or less on average.

(3) The sputtering target according to (1) or (2), the content of oxygen of the sintered body may be 50 to 2000 ppm.

(4) The sputtering target according to any one of (1) to (3) may have 50 μm or less of an average grain size of the metallic phase in the sputtering-target material.

(5) A producing method of a sputtering target of the present invention includes a step of: sintering a mixed powder of a powder containing Cu, Ga, and In and a Na compound powder to produce a sintered body containing Cu, Ga, In, and Na, wherein the powder containing Cu, Ga, and In is made of either one of: a binary or ternary alloy powder selected from the group consisting of Cu, Ga, and In; and a binary or ternary alloy powder selected from the group consisting of Cu, Ga, and In and a Cu powder, and an average particle size of the mixed powder is 1 to 70 μm.

(6) The producing method of the sputtering target according to (5), the Na compound powder and the powder containing Cu, Ga, and In may be mixed by dry blending method.

(7) The producing method of the sputtering target according to (5) or (6), the method may include either one of the steps of: drying the Na compound powder at a temperature of 70° C. or more before the mixed powder is prepared; and drying the mixed powder at a temperature of 70° C. or more before sintering the mixed powder.

(8) The producing method of the sputtering target according to any one of (5) to (7) may perform sintering of the mixed powder in a non-oxidizing atmosphere or vacuum in the step of sintering.

According to the above configurations, by suppressing the aggregate of Na compound, limiting the content of oxygen in the sputtering target and optimizing the average grain size of the metallic phase in the sputtering target as described above, a sputtering target can be obtained in which deflective strength and electrical resistance of the sputtering target is sufficiently secured, the density thereof is secured, the occurrence of discoloration and spots and abnormal discharge is suppressed even though Na is contained thereto, and furthermore, which has a high strength and is hard to crack.

The content of Na and the content of Ga in the present invention are the contents with respect to the total metal components other than F, S, and Se in the sputtering target, and as described below, it is calculated using a ratio of the total contents of each of Cu, Ga, In, and Na atoms in the sputtering target.

Na(at.%): Na/(Na+Cu+In+Ga)×100%

Ga(at.%): Ga/(Na+Cu+In+Ga)×100%

In(at.%): In/(Na+Cu+In+Ga)×100%

The reason of setting the content of Na contained in the Na compound within the above ranges is because when the content of Na exceeds 15 at. %, the mechanical strength of the sputtering target is significantly reduced and a sufficient sintered density cannot be secured, and at the same time, abnormal discharge increases during sputtering. On the other hand, when the content of Na is less than 0.05 at. %, the content of Na in the film becomes insufficient and the purpose of the addition of Na cannot be achieved.

The sputtering target according to the present invention has a structure in which a Na compound phase is dispersed in the sputtering-target material and an average grain size of the Na compound phase is 10 μm or less. Here, the average size is a circle-equivalent diameter of a projected area.

Since the sputtering target containing a Na compound contains a Na compound which is an insulating material, the dispersion of the Na compound phase is difficult in a conventional producing method. In a case where micro dispersion of the Na compound phase is not performed properly, when direct-current (DC) sputtering is performed, abnormal discharge called micro arc is easily occurred. The micro arc, depending on its extent, does not cause large damages to the sputtering target itself, but it causes bad effects to a film quality of a film obtained by sputtering. The present inventors have found that micro-arc-abnormal discharge caused by the Na compound can be significantly reduced when the average grain size of the Na compound is 10 μm or less. In addition, the Na compound positioned at a surface layer is inevitable to be in contact with ambient air, and when the average grain size thereof exceeds 10 μm, the amount of moisture adsorption increases and it becomes a cause of discoloration of a target surface.

In order to solve these problems, the sputtering target of the present invention enables a high-speed deposition under a condition of a DC sputtering or pulse-DC sputtering by optimizing a grain size of the Na compound phase as described above. That is, in the sputtering target of the present invention, discoloration of the target surface is suppressed in minimum by setting the average grain size of each of the above Na compound phases to 10 μm or less, and furthermore, a stable DC sputtering or pulse-DC sputtering is possible by suppressing the micro-arc-abnormal discharge caused by the Na compound.

In the sputtering target of the present invention, the theoretical density ratio in the sputtering target is 90% or more. The reason thereof is when the theoretical density ratio is less than 90%, the number of pores which are present in the sputtering target and communicated with ambient air increases, and the Na compound contained in the sputtering target adsorbs moisture from ambient air, and thereby, discoloration to the target occurs during production, storage, and use.

On the other hand, in the sputtering target whose density is high and which contains a large amount of the Na compound, brittleness is more likely to increase. In contrast, in the present invention, the deflective strength of the target is 60 N/mm² or more, and occurrence of cracks during machining process in the production of the target and sputtering is prevented.

Furthermore, when the Na compound having no conductivity is added to the sputtering target, abnormal discharge during sputtering is likely to occur, but in the present invention, a bulk resistivity of the target is 0.1 Ω*cm or less and thereby abnormal discharge is prevented.

Furthermore, when the Na compound is added to the sputtering target, the aggregates of the Na compound (hereinafter, also called Na compound aggregates) having 0.05 mm² or more easily adsorbs moisture in particular because their contact area with ambient air is large, and it was found that the aggregates thereof are the main cause of the occurrence of discoloration and spots of the surface of the sputtering target. The discoloration and spots caused by such the Na compound aggregates generated on the target surface and having 0.05 mm² or more cannot remove by press sputtering performing in the beginning of using a normal sputtering target, and as the result, impurities (hydrogen and oxygen) is contaminated in a deposited film. Moreover, a release of adsorbed moisture by the aggregates during sputtering leads to a local concentration of plasma, and significant abnormal discharge occurs around the spots due to the aggregates. Since the Na compound originally having a high vapor pressure is evaporated by a high temperature provided by this abnormal discharge, and additionally, the plasma is attracted, a cavity shaped abnormal discharge trace is formed in the vicinity of spots portion. Such significant abnormal discharge, namely, a sputtering target in which hard arc occurred, the surface condition is significantly destroyed and the sputtering target falls into a state that cannot be used in one or several of abnormal discharges. In contrast, in the present invention, the Na compound aggregate having a size of 0.05 mm² or more contained in an area of 1 cm² of the sputtering target surface is limited to one or less on average, and thereby, the occurrence of discoloration and spots is suppressed, and impurities contamination of the film, reduction of mechanical strength of the sputtering target and the occurrence of abnormal discharge during sputtering caused by the occurrence thereof can be prevented.

In the sputtering target according to the present invention, it is preferred that the content of oxygen be 50 to 2000 ppm.

That is, in this sputtering target, since the content of oxygen is 50 to 2000 ppm, the occurrence of NaO having high moisture adsorption properties can be prevented, and therefore, discoloration of the surface of the sputtering target can be further suppressed and reduction of mechanical strength in the sputtering target can be further suppressed.

When oxygen is present in the Cu—Ga sputtering target in which the Na compound is added, the oxygen and the Na compound gradually react to each other, NaO having high moisture adsorption properties is formed and discoloration of the sputtering target and reduction of mechanical strength thereof occur. In particular, since a possibility of discoloration of the sputtering target and reduction of mechanical strength is high when the content of oxygen exceeds 2000 ppm, the content of oxygen was set to 2000 ppm or less. On the other hand, since it is very difficult for the oxygen concentration in the sputtering target to be less than 50 ppm as a matter of practice, the lower limit of the oxygen concentration in the sputtering target was set to 50 ppm.

The sputtering target according to the present invention has 50 μm or less of an average grain size of the metallic phase in the sputtering-target material.

In this sputtering target, since the average grain size of the metallic phase in the sputtering-target material is 50 μm or less, the theoretical density ratio is 90% or more and even though the above high concentration Na compound is contained, toughness of the sputtering target can be well maintained. That is, as described above, in order to minimize the moisture adsorption of the sputtering target, the theoretical density ratio of the sputtering target is required to set to 90% or more; however, by improving the density of the sputtering target, brittleness is more likely to increase in the sputtering target of the present invention containing the Na compound. Therefore, setting the average crystal grain size of the metallic phase to 50 μm or less is effective to maintain toughness of the sputtering target. In addition, when the average grain size exceeds 30 μm, defects easily appear during machining of the sputtering target.

On the other hand, a producing method of the sputtering target according to the present invention includes a step of: sintering a mixed powder of a Na compound powder and a powder containing Cu, Ga, and In, and furthermore, the powder containing Cu, Ga, and In is made of a binary or ternary alloy powder selected from the group consisting of Cu, Ga, and In or is made of the binary or ternary alloy powder and Cu powder, and the average particle size is 1 to 70 μm.

Furthermore, in this producing method of the sputtering target, the Na compound powder and the powder containing Cu, Ga, and In are mixed by a dry blending method which does not use a solvent. In addition, this producing method of the sputtering target includes either one of the steps of: drying the Na compound powder at a temperature of 70° C. or more before the mixed powder is prepared; and drying the mixed powder at a temperature of 70° C. or more. This producing method of the sputtering target performs sintering of the mixed powder in a non-oxidizing atmosphere or vacuum in the step of sintering of the mixed powder.

In this producing method of the sputtering target, since the average particle size of the powder containing Cu, Ga, and In is set to 1 to 70 μm and the Na compound powder is mixed, a distribution of Na in the target uniforms easily with Na being contained, discoloration due to the moisture adsorption or the like of the Na compound and the occurrence of spots and abnormal discharge is suppressed.

When a fine metal powder (that is, fine metal powder including an alloy containing Cu, Ga, and In or pure Cu) and a fine Na compound powder are mixed in addition of the Na compound, a network of metal powder cannot be formed, conversely. The mechanical strength of the obtained sputtering target is reduced and also there is a case where conductivity is reduced, and therefore, the average particle size of the powder containing Cu, Ga, and In was set to 1 μm or more.

On the other hand, when the particle size of the powder containing Cu, Ga, and In is too large, the dispersion of the Na compound is insufficient. In addition, large aggregates of the Na compound are formed, and they cause discoloration in the sputtering target, reduction of the mechanical strength, and abnormal discharge during sputtering. In addition, in the sputtering target produced by using a powder containing a large particle size of Cu, Ga, and In, the Na compound is likely to concentrate at a grain boundary of the metallic phase. This also causes discoloration in the sputtering target, reduction of the mechanical strength, and abnormal discharge. In contrast to this, the average particle size of the powder containing Cu, Ga, and In was set to 70 μm or less.

Furthermore, in the producing method of the sputtering target of the present invention, the Na compound powder and the powder containing Cu, Ga, and In are mixed by a dry blending method which does not use a solvent. Thus, the present invention can suppress an uneven re-deposition of Na compound and an enlargement of grains due to a wet blending and a mixing of moisture and oxygen due to a wet blending. Thus, problems such as uneven deposition of moisture and oxygen in the solvent and also the Na compound during drying are suppressed, and moreover, a sputtering target, which has less abnormal discharge during sputtering, has high strength and is hard to crack, can be produced.

In addition, in the producing method of the sputtering target of the present invention, the method is preferred to include the step of: drying the Na compound powder at a temperature of 70° C. or more before the mixed powder is prepared or drying the mixed powder at a temperature of 70° C. or more after mixing the Na compound powder and the mixed powder.

In these producing methods of the sputtering target, since the methods have either one of the steps of drying the Na compound powder at a temperature of 70° C. or more before the mixed powder is prepared and drying the mixed powder at a temperature of 70° C. or more, the dispersion properties of the grains of the Na compound are maintained, a re-aggregation can be suppressed after mixing raw material powders along with reducing of the content of oxygen.

The producing method of the sputtering target according to the present invention performs sintering of the mixed powder in a non-oxidizing atmosphere or vacuum in the step of sintering the mixed powder.

That is, in this producing method of the sputtering target, since the mixed powder is sintered in a non-oxidizing atmosphere or vacuum, the content of oxygen can be further reduced.

### Effects of the Invention

The present invention has the following effects.

That is, according to a sputtering target related to the present invention and a producing method thereof, the sputtering target contains Ga: 2 to 30 at. %, In: 15 to 45 at. %, Na: 0.05 to 15 at. % as metal components other than F, S and Se, and the remainder composed of Cu and inevitable impurities, and in the sputtering target material, it has a composition in which a Na compound phase is dispersed and an average grain size of the Na compound phase is 10 μm or less. Therefore, discoloration of the sputtering target caused by moisture adsorption and abnormal discharge during sputtering is suppressed even though Na is contained, and furthermore, the sputtering target has a high strength and is hard to crack. Thus, the present invention has a high mass-productivity, can achieve the addition of Na to the light adsorbing layer, and can produce a solar battery having a high power generation efficiency by depositing a light adsorbing layer of a CIGS-thin-film-type-solar battery by sputtering using the sputtering target of the present invention.

### BRIEF DESCRIPTION OF THE DRAWINGS

FIG. 1 is a picture showing composition images (COMP images) by electron probe microanalyzer (EPMA) and elemental mapping images of each Cu, In, Ga and Na according to the sputtering target of the present invention.

FIG. 2 is a picture showing a Na compound aggregate present on the surface of the sputtering target of the present invention.

### EMBODIMENTS OF THE INVENTION

Hereinafter, an embodiment of a sputtering target and producing method thereof according to the present invention will be described.

[Sputtering Target]

The sputtering target of the present embodiment has a component composition containing Ga: 2 to 30 at. %, In: 15 to 45 at. %, Na: 0.05 to 15 at. % as metal components other than F, S and Se in the sputtering target, and the remainder composed of Cu and inevitable impurities. The sputtering target has a composition in which Na is contained in a state of Na compound formed of at least one form of sodium fluoride, sodium sulfide, and sodium selenide, and a Na compound phase is dispersed in the target material, and an average grain size of the Na compound phase is 10 μm or less.

In addition, the sputtering target of the present embodiment is preferred to have a theoretical density ratio being 90% or more, a deflective strength being 100 N/mm² or more, a bulk resistivity being 0.1 Ω*cm or less, and the number of Na compound aggregates having a size of 0.05 mm² or more contained in an area of 1 cm² of the sputtering target surface being one or less on average.

Furthermore, the content of oxygen in the sputtering target is preferably 50 to 2000 ppm, and the average grain size of a metallic phase in the target material is preferably 50 μm or less.

### <With Respect to “Theoretical Density Ratio”>

A measurement of the theoretical density ratio of the target is calculated from weight/size.

That is, with respect to the theoretical density ratio, since a density (theoretical density) of the basis material having no holes is changed by an actual ratio of Cu/In/Ga, types of incorporated raw materials, and sintering conditions, the density is calculated as follows.

First, a Cu—In—Ga metal mixture which has the same ratio to the ratio of Cu/In/Ga in the sputtering target of the present embodiment is melted at 1200° C., then the above metal mixture is cast, the density of an ingot, which is obtained by slow cooling, has the size of 10 cm×10 cm×10 cm, and has no defects, is measured, and this is defined as the theoretical density of a Cu—In—Ga alloy having the above ratio.

Theoretical density of a Na compound, for example NaF is defined as 2.79 g/cm³, Na₂S is defined as 1.86 g/cm³, and Na₂Se is defined as 2.65 g/cm³. Theoretical density of the sputtering target is calculated by using the above theoretical density of Cu—In—Ga alloy and theoretical density of the Na compound, and the content of Cu, In, and Ga and the content of the Na compound in the sputtering target of the present embodiment.

Therefore the theoretical density ratio can be calculated by “(weight/density of the target obtained by the size)/theoretical density of the target×100%”.

### <With Respect to “Deflective Strength”>

With respect to deflective strength, the sintered target is machined so as to comply with JIS R1601, and the strength against bending (deflective strength) is measured. That is, the target is machined in a shape of a rod, the size of which is 40 mm in length×4 mm in width×3 mm in thickness, and deflective strength is measured.

### <With Respect to “Electrical Resistance”>

The electrical resistance is measured by using a four probe method.

### <With Respect to “Aggregate”>

With respect to a measurement of the size of the aggregates, 100 cm² of the target surface is observed by an optical microscope using 10 times of a magnification and is photographed (for example, refer to the picture of FIG. 2). The size of the aggregates is calculated by the black spots photographed in this picture, and the number of the Na compound aggregates having 0.05 mm² or more is counted. Furthermore, checking whether the aggregates are the Na compounds is performed by using EDX function of SEM. In addition, the average number of the Na compound aggregates having 0.05 mm² or more present in an area of 1 cm² of the target surface is calculated by using the average in an area of 100 cm² of the target surface.

### <With Respect to “Average Grain Size of Na Compound Phase”>

Next, with respect to the average grain size of the Na compound phase in the basis material of the sputtering target, in order for conducting a measurement thereof, samples for observation are produced as follows, and the grain size thereof is calculated.

First, an arbitrary part of the sintered sputtering target is cut, and samples are made which have a block shape and have the size of substantially 5×10×3 mm. Next, the samples are polished to have a surface roughness Ra: 0.5 μm or less, and a surface for observation is made. Furthermore, a plurality of images of the observation surface is photographed by 1000 times of a magnification of SEM, a cross-section area of the Na compound phase in 1000 μm×1000 μm is calculated, and after converting to a circle-equivalent diameter of a projected area, the average grain size of the grains in the observation area is calculated.

### <With Respect to Average Grain Size of Metallic Phase>

A producing method of samples for the observation in order for measuring the average grain size of the metallic phase and a calculation of the average grain size are as follows.

First, the observation surface of the samples having a block shape is etched by dipping 5 seconds in an etchant prepared by 50 ml of pure water, 5 ml of a hydrogen peroxide solution and 45 ml of aqueous ammonia. Next, an alloy composition is photographed by observing an etching surface using 250 times of a magnification of the optical microscope. At this time, a cross-sectional area of crystals in the observation area of 500 μm×1000 μm is calculated, is converted to a circle-equivalent diameter of a projected area, and then, the average grain size of the grains in the observation area is calculated.

### [Producing Method of Sputtering Target]

Next, a producing method of the sputtering target of the above embodiment is explained

The producing method of the sputtering target of the present embodiment includes a step of: sintering a mixed powder of a Na compound powder and a powder containing Cu, In, and Ga and thereby producing a sinter body. The powder containing Cu, In, and Ga is made of a binary or ternary alloy powder selected from the group consisting of Cu, In, and Ga or is made of the binary or ternary alloy powder and a Cu powder, and the average grain size is 1 to 70 μm. An impurity concentration of metal element of the powder containing Cu, In, and Ga is preferably 0.1 at. % or less, and furthermore, is more preferably 0.01 at. % or less. Moreover, the average grain size is preferably 5 to 70 μm in order to reduce the content of oxygen in the powder containing Cu, In, and Ga.

### <Na Compound Powder>

A Na compound powder is preferred to have purity of 95% or more, and furthermore, is preferred to have 3N or more, and a primary particle size is preferably 0.01 to 1.0 μm in the consideration of a mixing properties between the Na compound powder and the powder containing Cu, In, and Ga along with suppressing a raise of the content of oxygen.

In addition, in order to achieve the content of oxygen of 2000 ppm or less in the target, adsorbed moisture in the Na compound is preferably removed in advance in a drying condition of 70° C. before mixing it. For example, it is effective to dry at 120° C. for 10 hours in a vacuum condition in a vacuum dryer.

In addition, since the Na compound has high moisture adsorption properties and has properties of dissolving in water, a wet-type pulverizing-mixing device is preferably used.

### <Preparation of Mixed Powder>

In preparing a mixed powder of the Na compound and the powder containing Cu, In, and Ga, a crushing method using the pulverizing-mixing device (for example, a ball mill, jet mill, Henschel mixer, Attritor or the like) and different mixing methods of the following (1) to (3) can be utilized.

(1) A method in which crushing of the Na compound powder and mixing of the powder containing Cu, In, and Ga thereto are performed separately.

An average secondary particle size of the Na compound obtained by crushing is preferably 1 to 5 μm. The crushing step is preferably performed under a drying environment of humidity RH: 40% or less. As described above, the Na compound powder obtained by after such crushing is preferably dried at 70° C. or more before mixing it.

Then, this Na compound powder and the powder containing Cu, In, and Ga and prepared in a target composition are mixed under a drying environment of relative humidity RH: 40% or less using a dry-type-mixing device, thereby making a mixed powder. In addition, the mixing is more preferably performed in a reducing atmosphere.

(2) A method in which crushing of the Na compound powder and mixing of the powder containing Cu, In, and Ga thereto are performed at the same time.

An already dried Na compound powder and the powder containing Cu, In, and Ga and prepared in a target composition are filled in the pulverizing-mixing device at the same time, mixing and crushing of the Na compound powder are performed at the same time, and the crushing is stopped when the secondary particle size of the Na compound powder becomes 5 μm or less. In addition, the mixing is preferably performed under a drying environment of relative humidity RH: 40% or less and is more preferably performed in a reducing atmosphere.

(3) A method in which a plurality of powder containing Cu, In, and Ga being different in concentration of Ga and In is used.

First, a powder containing Cu, In, and Ga (a high Ga—In powder) in which the content of Ga or In is large than the ratio of Cu/In/Ga of the target composition and a powder containing Cu, In, and Ga in which the content of Ga or In is small than the ratio of Cu/In/Ga of the target composition or a Cu powder (a low Ga—In powder) are prepared.

The high Ga—In powder is mixed to the already dried Na compound powder, and then furthermore, the low Ga—In powder is added therein. The powders are mixed so as to be uniformed and thereby making a mixed powder.

The above mixing is performed in a low humidity environment such as the above (1) and (2). In addition, it is more preferably performed in a reducing atmosphere.

In any of (1) to (3), it is preferable to remove the adsorbed moisture in the mixed powder after mixing, for example, drying at 80° C. for 3 hours or more in a vacuum environment of in a vacuum dryer is effective.

Next, the raw material powders mixed with any of the above methods (1) to (3) are stored by sealing in a bag made of a plastic resin in the dry environment at a humidity RH: 30% or less. This is to prevent from moisture adsorption of the Na compound and aggregation due to moisture adsorption.

### <With Respect to “Sintering Step”>

In order to prevent oxidation during sintering of the Cu—In—Ga powder, the sintering is preferably carried out in a non-oxidizing reducing atmosphere, in a vacuum, or in an inert gas atmosphere.

As a method of sintering the mixed powder, for example, the following three methods can be applied.

1. The powder is filled into a mold, is filled in a molded body or shaping mold which is cold-pressing-molded, a compact having a constant bulk density is formed by tapping, and it is sintered in a vacuum, inert gas or a reducing atmosphere. Here, the tapping is an act giving a vibration by tapping or the like the mold, molded body or shaping mold and changing a density state of the mixed powder in the mold or the like from a non-uniform state to a uniform state. In this way, the mixed powder has a constant bulk density.

2. The mixed powder is hot-pressed in a vacuum or inert gas atmosphere.

3. The mixed powder is sintered in an HIP process (hot isostatic pressing method).

### <Machining or the Like>

Next, a Cu—In—Ga—Na-compound-sintered body obtained in the above sintering step is machined to a specified shape by using a usually discharge machining, a cutting or grinding, thereby the sputtering target of the present embodiment is produced. At this time, since the Na compound has properties of dissolving in water, during machining, a dry method which does not use a coolant or a wet method which uses a coolant without including water is preferable. Also, after pre-machining by the wet method, there is a method further carrying out a precision machining of the surface by dry method.

Next, the sputtering target after the above machining is bonded to a backing plate made of Cu, SUS (stainless steel), or other metal (e.g., Mo) using In as solder and is subjected to sputtering.

In addition, when storing the sputtering target which has already machined, in order to prevent from oxidation and moisture adsorption, carrying out a vacuum pack or inert gas replacing pack of the entire sputtering target is preferable.

### <Method of Using the Sputtering Target>

The sputtering target made by the above is subjected to DC magnetron sputtering by using Ar gas as a sputtering gas. In this case, a pulsed DC power source for adding a pulse voltage is preferably used; however, depending on the content of the Na compound, sputtering by a DC power source without pulses is also possible. Also, input power during sputtering is preferably 1 to 10 W/cm².

### Effects in the Present Embodiment

According to the above, since the sputtering target of the present invention has a composition in which the Na compound phase is dispersed in the sputtering-target material and the average grain size of the Na compound phase is 10 μm or less, a sputtering target can be obtained in which the occurrence of discoloration and spots and abnormal discharge are suppressed even though Na is contained thereto, and furthermore, which has a high strength and is hard to crack.

In addition, the target density is sufficiently secured by having the theoretical density ratio being 90% or more, a deflective strength being 100 N/mm² or more, a bulk resistivity being 0.1 Ω*cm or less, and the number of Na compound aggregates having a size of 0.05 mm² or more contained in an area of 1 cm² of the sputtering target surface being one or less on average, and accordingly, abnormal discharge caused by the Na compound is suppressed by securing of a deflective strength and electrical resistance and suppressing of aggregate, and a stable DC sputtering or pulse-DC sputtering becomes possible.

Furthermore, in the sputtering target of the present embodiment, since the content of oxygen is 50 to 2000 ppm, the occurrence of NaO having high moisture adsorption properties can be prevented, and discoloration and reduction of mechanical strength can be further suppressed.

Also, since the average grain size of the metallic phase in the sputtering-target material of the present embodiment is 50 μm or less, the toughness of the target can be well maintained even if the theoretical density ratio is 90% or more and a high concentration of the Na compound is contained therein.

In the producing method of the sputtering target of the present embodiment, the average particle size of the powder containing Cu, In, and Ga is set to 1 to 70 μm, and a sputtering target can be produced which suppresses a decrease in the mechanical strength and electrical conductivity and the occurrence of discoloration.

Furthermore, since the methods have the steps of drying the Na compound powder at a temperature of 70° C. or more before the mixed powder is prepared or drying the mixed powder at a temperature of 70° C. or more, the dispersion properties of the grains of the Na compound is maintained, and a re-aggregation can be suppressed after mixing the raw material powders along with reducing of the content of oxygen.

### EXAMPLES

Next, evaluation results of the sputtering target and producing method thereof according to the present invention will be described through the examples made based on the above embodiment.

### Example

First, a Cu—In—Ga alloy powder, Cu—In alloy powder, Cu—Ga alloy powder, Cu powder (having purity of 4N), and a Na compound powder having an average primary particle size of 1 μm and purity of 3N, each of which have a component composition and particle size shown in Table 1 were blended to be in amounts shown in Table 1, and mixed powders of Examples 1 to 14 were obtained. Each of the Cu—In—Ga alloy powder, Cu—In alloy powder, and Cu—Ga alloy powder can be obtained by pulverizing a cast ingot of Cu—In—Ga alloy, Cu—In alloy, and Cu—Ga alloy, but these can be obtained by an atomized method or the like. These Na compound powders were used directly in the mixing as described in Table 1, or dried at above a predetermined vacuum environment. Then, as shown in Table 1, the dried above raw powders were put in a polyethylene pot having a volume of 10 L, and furthermore, a zirconia ball having a diameter of 2 mm and dried at 80° C. for 10 hours was put in the pot, and the raw material powders were mixed for the specified time by a ball mill. This mixing was carried out in a nitrogen atmosphere. In addition, the zirconia ball having a diameter of 1 mm is light weight, and has the effect of dispersing mixed without crushing Cu powder, Cu—In—Ga alloy powder, Cu—In alloy powder, and a Cu—Ga alloy powder. In addition, the weight ratio of ball-to-powder, ball:powder=2:1 has the most excellent dispersion effect. In Example 14, ethanol was added 2 liters and subjected to wet mixing. The powder after mixing was dried at 90° C. for 16 hours in a vacuum dryer.

Then, the obtained mixed powder were sintered at the specified conditions given in Table 2 after it was sieved and further dried at the above described predetermined environment.

When sintering at atmospheric pressure, first, the mixed powder was filled into a metal mold and was pressed at room temperature at a pressure of 1500 kgf/cm², to produce a molded body. The molded body was sintered in a mixed atmosphere of nitrogen and 3% hydrogen to obtain a sintered body of high density of Examples 1 to 14.

In a case of a hot pressing (HP), a vacuum hot pressing was carried out by filling the raw material powders to an iron mold. Moreover, a hydrostatic hot pressing (HIP) can be also used, and in this case, the molded body was made in the same way as sintering at atmospheric pressure, and the molded body was charged in stainless steel container having 0.5 mm of thickness, and then, the sealed through the vacuum degassing, and a HIP processing was carried out.

The sintered body produced in the above way was subjected to dry cutting, and thereby, sputtering targets of Examples 1 to 14 having diameter 125 (mm)×thickness 5 (mm) were produced.

For comparison, as shown in Table 4 and Table 5, under conditions deviating from the scope of the present invention, sputtering targets of Comparative Examples 1 to 10 were produced.

In the sputtering targets of Comparative Examples 9 and 10, after each of the raw materials of In, Ga, Cu was dissolved in vacuum environment, a Na compound powder is added, the molten metal is cast into a mold, and a casting body containing Na compounds was produced. In the sputtering target of Comparative Example 4, the raw materials mixed in powder were dissolved in vacuum environment, the molten metal is cast in a mold, and thereby, a casting body containing the Na compound was produced.

TABLE 1

| | Cu—In—Ga | | | | Cu—Ga | | Cu—In | | Cu | |
|---|---|---|---|---|---|---|---|---|---|---|
| | alloy powder | | | | alloy powder | | alloy powder | | powder | |
| | | | | Additive | | Additive | | Additive | Additive | Average particle |
| | In | Ga | Cu | amount | Ga | amount | In | amount | amount | size of mixed |
| | (at %) | (at %) | (at %) | (g) | (at %) | (g) | (at %) | (g) | (g) | powder (μm) |
| Example 1 | 30 | 12 | remaining | 6000 | | | | | | 56 |
| Example 2 | 25 | 15 | remaining | 6000 | | | | | | 62 |
| Example 3 | 45 | 5 | remaining | 6000 | | | | | | 45 |
| Example 4 | 30 | 28 | remaining | 6000 | | | | | | 57 |
| Example 5 | | | | | 50 | 2000 | 40 | 3500 | 500 | 32 |
| Example 6 | | | | | 30 | 2000 | 50 | 3500 | | 69 |
| Example 7 | | | | | 35 | 3000 | 60 | 2500 | 500 | 24 |
| Example 8 | 45 | 25 | remaining | 5500 | | | | | 500 | 29 |
| Example 9 | 30 | 15 | remaining | 6000 | | | | | | 55 |
| Example 10 | 30 | 10 | remaining | 6000 | | | | | | 64 |
| Example 11 | | | | | 10 | 2800 | 70 | 2000 | 200 | 34 |
| Example 12 | 40 | 4 | remaining | 5500 | | | | | 1000 | 6 |
| Example 13 | 35 | 15 | remaining | 5500 | | | | | 500 | 39 |
| Example 14 | 35 | 15 | remaining | 5500 | | | | | 500 | 39 |

| | Additive amount | | | | | | | |
|---|---|---|---|---|---|---|---|---|
| | of Na compound | | | Drying conditions | Solvent for mixing | | Mixing | |
| | NaF | Na₂S | Na₂Se | of Na compound | | Amount | time | Drying conditions |
| | (g) | (g) | (g) | before mixing | Material | used | Hour | after mixing |
| Example 1 | 500 | | | 80° C., | | | 3 | 80° C., |
| | | | | 8 hours | | | | 8 hours |
| Example 2 | 50 | | | | | | 2 | 70° C., |
| | | | | | | | | 8 hours |
| Example 3 | | | 3 | | | | 5 | 80° C., |
| | | | | | | | | 10 hours |
| Example 4 | | 5 | | | | | 4 | 90° C., |
| | | | | | | | | 3 hours |
| Example 5 | 5 | | | | | | 3 | 80° C., |
| | | | | | | | | 8 hours |
| Example 6 | | | 5 | 70° C., | | | 5 | |
| | | | | 5 hours | | | | |
| Example 7 | 300 | | | 80° C., | | | 8 | |
| | | | | 8 hours | | | | |
| Example 8 | 5 | | | | | | 5 | |
| Example 9 | 11 | 1 | | | | | 7 | |
| Example 10 | 0.5 | 2 | | | | | 2 | |
| Example 11 | | | 2.5 | 70° C., | | | 3 | |
| | | | | 5 hours | | | | |
| Example 12 | | 4 | | 70° C., | | | 4 | |
| | | | | 5 hours | | | | |
| Example 13 | 2 | | | | | | 1 | |
| Example 14 | 10 | | | | ethanol | 2000 ml | 5 | 90° C., |
| | | | | | | | | 16 hours |

TABLE 2

| | | | | | Sintering body composition | | | | |
|---|---|---|---|---|---|---|---|---|---|
| | Sintering condition | | | | (measured value) | | | | Average grain |
| | Sintering | Temperature | Pressure | Maintaining | In | Ga | Cu | Na | size of Na |
| | method | (° C.) | (kgf/cm²) | time (hour) | (at %) | (at %) | (at %) | (at %) | compound (μm) |
| Example 1 | HP | 200 | 1000 | 2 | 26 | 10 | remaining | 12.00 | 7 |
| Example 2 | HIP | 200 | 1700 | 1 | 25 | 15 | remaining | 1.50 | 4 |
| Example 3 | sintering in | 230 | 0 | 5 | 45 | 5 | remaining | 0.05 | 3 |
| | controlled | | | | | | | | |
| | atmospher | | | | | | | | |
| Example 4 | sintering in | 230 | 0 | 5 | 30 | 28 | remaining | 0.15 | 2 |
| | controlled | | | | | | | | |
| | atmospher | | | | | | | | |
| Example 5 | HP | 260 | 1200 | 2 | 20 | 19 | remaining | 0.15 | 4 |
| Example 6 | HIP | 240 | 1700 | 1 | 28 | 12 | remaining | 0.10 | 6 |
| Example 7 | HP | 300 | 1200 | 2 | 18 | 17 | remaining | 8.10 | 7 |
| Example 8 | HIP | 150 | 1500 | 1 | 40 | 21 | remaining | 0.15 | 7 |
| Example 9 | HP | 200 | 1000 | 2 | 30 | 15 | remaining | 0.40 | 8 |
| Example 10 | HP | 200 | 1000 | 2 | 30 | 10 | remaining | 0.12 | 8 |
| Example 11 | HP | 230 | 1000 | 2 | 21 | 7 | remaining | 0.05 | 3 |
| Example 12 | sintering in | 250 | 0 | 5 | 32 | 3 | remaining | 0.13 | 3 |
| | controlled | | | | | | | | |
| | atmospher | | | | | | | | |
| Example 13 | HP | 200 | 800 | 2 | 30 | 13 | remaining | 0.06 | 9 |
| Example 14 | HP | 160 | 1200 | 1 | 35 | 15 | remaining | 0.33 | 9 |

| | | | | | | Average crystal | Occurrence |
|---|---|---|---|---|---|---|---|
| | Theoretical | Deflective | Bulk | Na compound on | Content of | grain size | of spots or |
| | density | strength | resistance | target surface | oxygen | of metallic | color uneven- |
| | ratio (%) | (N/mm²) | (Ω · cm) | (pieces/cm²) *1 | (ppm) | phase (μm) | ness *2 |
| Example 1 | 93 | 62 | 0.08 | 0.4 | 896 | 27 | None |
| Example 2 | 96 | 170 | 0.02 | 0.1 | 473 | 32 | None |
| Example 3 | 91 | 53 | 0.01 | 0 | 59 | 48 | None |
| Example 4 | 90 | 54 | 0.009 | 0.1 | 96 | 46 | None |
| Example 5 | 96 | 184 | 0.008 | 0.1 | 243 | 32 | None |
| Example 6 | 95 | 267 | 0.007 | 0.2 | 231 | 29 | None |
| Example 7 | 91 | 71 | 0.06 | 0.3 | 698 | 15 | None |
| Example 8 | 94 | 105 | 0.01 | 0.1 | 359 | 39 | None |
| Example 9 | 96 | 80 | 0.01 | 0.1 | 529 | 33 | None |
| Example 10 | 96 | 79 | 0.008 | 0.1 | 98 | 31 | None |
| Example 11 | 95 | 101 | 0.006 | 0 | 132 | 22 | None |
| Example 12 | 91 | 56 | 0.01 | 0.1 | 122 | 49 | None |
| Example 13 | 93 | 67 | 0.005 | 0 | 450 | 27 | None |
| Example 14 | 94 | 88 | 0.09 | 0.9 | 1980 | 24 | None |

*1: The number of Na compound aggregates having 0.05 mm² or more in an area of 1 cm². 100 cm² is measured and the average thereof is calculated.
*2: The results of a visual observation after leaving for 8 hous in atmosphere (25° C. and relative humidity of 60%).

TABLE 3

| | | | | | The number of | | | | |
|---|---|---|---|---|---|---|---|---|---|
| | | | | | times of abnormal | | | | |
| | Cracking/ | | | The number of | discharge during | | | | |
| | chipping | Continuous | State of target | times of abnormal | continuous dis- | | | | |
| | caused by | discharged | surface after | discharge during | charge (signifi- | Sputtering film composition | | | |
| | cutting | performed | continuous | continuous dis- | cant abnormal | In | Ga | Cu | Na |
| | machining | time | discharge | charge (micro arc) | discharge) | (at %) | (at %) | (at %) | (at %) |
| Example 1 | None | 10 min | Good | 98 | None | 28 | 8 | remaining | 9.10 |
| Example 2 | None | 10 min | Good | 66 | None | 26 | 14 | remaining | 1.20 |
| Example 3 | None | 10 min | Good | 8 | None | 48 | 5 | remaining | 0.05 |
| Example 4 | None | 10 min | Good | 37 | None | 31 | 28 | remaining | 0.12 |
| Example 5 | None | 10 min | Good | 21 | None | 23 | 19 | remaining | 0.11 |
| Example 6 | None | 10 min | Good | 13 | None | 29 | 13 | remaining | 0.08 |
| Example 7 | None | 10 min | Good | 87 | None | 19 | 18 | remaining | 6.45 |
| Example 8 | None | 10 min | Good | 211 | None | 40 | 22 | remaining | 0.14 |
| Example 9 | None | 10 min | Good | 356 | None | 31 | 15 | remaining | 0.29 |
| Example 10 | None | 10 min | Good | 194 | None | 31 | 10 | remaining | 0.06 |
| Example 11 | None | 10 min | Good | 10 | None | 20 | 7 | remaining | 0.03 |
| Example 12 | None | 10 min | Good | 42 | None | 33 | 4 | remaining | 0.10 |
| Example 13 | None | 10 min | Good | 108 | None | 30 | 12 | remaining | 0.04 |
| Example 14 | None | 10 min | Good | 863 | None | 35 | 15 | remaining | 0.22 |

TABLE 4

| | Cu—In—Ga | | | | Cu—Ga | | Cu—In | | Cu | |
|---|---|---|---|---|---|---|---|---|---|---|
| | alloy powder | | | | alloy powder | | alloy powder | | powder | |
| | | | | Additive | | Additive | | Additive | Additive | Average particle |
| | In | Ga | Cu | amount | Ga | amount | In | amount | amount | size of mixed |
| | (at %) | (at %) | (at %) | (g) | (at %) | (g) | (at %) | (g) | (g) | powder (μm) |
| Comparative | 30 | 12 | remaining | 6000 | | | | | | 100 |
| Example 1 | | | | | | | | | | |
| Comparative | 25 | 15 | remaining | 6000 | | | | | | 81 |
| Example 2 | | | | | | | | | | |
| Comparative | 45 | 5 | remaining | 6000 | | | | | | 0.3 |
| Example 3 | | | | | | | | | | |
| Comparative | 30 | 28 | remaining | 6000 | | | | | | 100 |
| Example 4 | | | | | | | | | | |
| Comparative | | | | | 50 | 2000 | 40 | 3500 | 500 | 32 |
| Example 5 | | | | | | | | | | |
| Comparative | | | | | 30 | 2000 | 50 | 3500 | | 69 |
| Example 6 | | | | | | | | | | |
| Comparative | | | | | 35 | 3000 | 60 | 2500 | 500 | 24 |
| Example 7 | | | | | | | | | | |
| Comparative | 45 | 25 | remaining | 5500 | | | | | 500 | 29 |
| Example 8 | | | | | | | | | | |
| | In powder | Ga powder | Cu powder | | | | | | | |
| | Incorpo- | Incorpo- | Incorpo- | | | | | | | |
| | rating | rating | rating | | | | | | | |
| | weight | weight | weight | | | | | | | |
| | (g) | (g) | (g) | | | | | | | |
| Comparative | 1500 | 500 | 3000 | | | | | | | |
| Example 9 | | | | | | | | | | |
| Comparative | 2000 | 1000 | 3000 | | | | | | | |
| Example 10 | | | | | | | | | | |

| | Additive amount | | | | | | | |
|---|---|---|---|---|---|---|---|---|
| | of Na compound (g) | | | Drying conditions | Solvent for mixing | | Mixing | |
| | NaF | Na₂S | Na₂Se | of Na compound | | Amount | time | Drying conditions |
| | (g) | (g) | (g) | before mixing | Material | used | Hour | after mixing |
| Comparative | 750 | | | | | | 3 | |
| Example 1 | | | | | | | | |
| Comparative | 50 | | | | | | 0.2 | |
| Example 2 | | | | | | | | |
| Comparative | | | 150 | | | | 0.5 | |
| Example 3 | | | | | | | | |
| Comparative | | 15 | | | | | 4 | |
| Example 4 | | | | | | | | |
| Comparative | 5 | | | | | | 3 | |
| Example 5 | | | | | | | | |
| Comparative | | | 5 | | | | 0.3 | |
| Example 6 | | | | | | | | |
| Comparative | 300 | | | | | | 0.5 | |
| Example 7 | | | | | | | | |
| Comparative | 5 | | | | | | 0.1 | |
| Example 8 | | | | | | | | |
| Comparative | 11 | 1 | | | | | | |
| Example 9 | | | | | | | | |
| Comparative | 0.5 | 2 | | | | | | |
| Example 10 | | | | | | | | |

TABLE 5

| | | | | | Sintering body composition | | | | |
|---|---|---|---|---|---|---|---|---|---|
| | Sintering condition | | | | (measured value) | | | | Average grain |
| | Sintering | Temperature | Pressure | Maintaining | In | Ga | Cu | Na | size of Na |
| | method | (° C.) | (kgf/cm²) | time (hour) | (at %) | (at %) | (at %) | (at %) | compound (μm) |
| Comparative | HP | 200 | 1000 | 2 | 23 | 10 | remaining | 18.00 | 13 |
| Example 1 | | | | | | | | | |
| Comparative | HIP | 200 | 1700 | 1 | 26 | 15 | remaining | 1.50 | 21 |
| Example 2 | | | | | | | | | |
| Comparative | sintering in | 230 | 0 | 5 | 42 | 5 | remaining | 3.10 | 16 |
| Example 3 | controlled | | | | | | | | |
| | atmospher | | | | | | | | |
| Comparative | solution | | | | 30 | 25 | remaining | 0.05 | 53 |
| Example 4 | process | | | | | | | | |
| Comparative | HP | 260 | 1200 | 2 | 20 | 18 | remaining | 0.11 | 14 |
| Example 5 | | | | | | | | | |
| Comparative | HIP | 240 | 1700 | 1 | 28 | 13 | remaining | 0.10 | 11 |
| Example 4 | | | | | | | | | |
| Comparative | HP | 300 | 1200 | 2 | 18 | 18 | remaining | 8.00 | 11 |
| Example 7 | | | | | | | | | |
| Comparative | HIP | 150 | 1500 | 1 | 40 | 21 | remaining | 0.15 | 13 |
| Example 8 | | | | | | | | | |
| Comparative | solution | | | | 21 | 12 | remaining | 0.02 | 64 |
| Example 9 | process | | | | | | | | |
| Comparative | solution | | | | 22 | 19 | remaining | 0.03 | 59 |
| Example 10 | process | | | | | | | | |

| | | | | | | Average crystal | Occurrence |
|---|---|---|---|---|---|---|---|
| | Theoretical | Deflective | Bulk | Na compound on | Content of | grain size | of spots or |
| | density | strength | resistance | target surface | oxygen | of metallic | color uneven- |
| | ratio (%) | (N/mm²) | (Ω · cm) | (pieces/cm²) *1 | (ppm) | phase (μm) | ness *2 |
| Comparative | 91 | 35 | 0.2 | 11 | 1036 | 81 | Large amount |
| Example 1 | | | | | | | of spots |
| Comparative | 95 | 46 | 0.02 | 8 | 450 | 61 | Large amount |
| Example 2 | | | | | | | of spots |
| Comparative | 90 | 49 | 0.008 | 11 | 2600 | 0.9 | Large amount |
| Example 3 | | | | | | | of spots |
| Comparative | 100 | 34 | 0.001 | 1 | 10 | 2910 | Spots |
| Example 4 | | | | | | | |
| Comparative | 96 | 105 | 0.008 | 2 | 297 | 32 | Spots |
| Example 5 | | | | | | | |
| Comparative | 94 | 68 | 0.007 | 1 | 431 | 49 | Spots |
| Example 4 | | | | | | | |
| Comparative | 91 | 81 | 0.03 | 6 | 1641 | 15 | Large amount |
| Example 7 | | | | | | | of spots |
| Comparative | 93 | 90 | 0.01 | 1 | 422 | 37 | Spots |
| Example 8 | | | | | | | |
| Comparative | 100 | 33 | 0.002 | 1 | 12 | 6400 | Spots |
| Example 9 | | | | | | | |
| Comparative | 100 | 46 | 0.003 | 1 | 16 | 5350 | Spots |
| Example 10 | | | | | | | |

*1: The number of Na compound aggregates having 0.05 mm² or more in an area of 1 cm². 100 cm² is measured and the average thereof is calculated.
*2: The results of a visual observation after leaving for 8 hous in atmosphere (25° C. and relative humidity of 60%).

TABLE 6

| | | | | | The number of | | | | |
|---|---|---|---|---|---|---|---|---|---|
| | | | | | times of abnormal | | | | |
| | Cracking/ | | | The number of | discharge during | | | | |
| | chipping | Continuous | State of target | times of abnormal | continuous dis- | | | | |
| | caused by | discharged | surface after | discharge during | charge (signifi- | Sputtering film composition | | | |
| | cutting | performed | continuous | continuous dis- | cant abnormal | In | Ga | Cu | Na |
| | machining | time | discharge | charge (micro arc) | discharge) | (at %) | (at %) | (at %) | (at %) |
| Comparative | cutout | Stopped | signigficant | | present | could not obtain a measurable film | | | |
| Example 1 | occurred | after 2 | abnormal | | | | | | |
| | | min | discharge traces | | | | | | |
| Comparative | None | 10 min | signigficant | 64832 | present | could not obtain a measurable film | | | |
| Example 2 | | | abnormal | | | | | | |
| | | | discharge traces | | | | | | |
| Comparative | None | Stopped | signigficant | | present | could not obtain a measurable film | | | |
| Example 3 | | after 9 | abnormal | | | | | | |
| | | min | discharge traces | | | | | | |
| Comparative | chipping | 10 min | signigficant | 28845 | present | 30 | 25 | remaining | 0.03 |
| Example 4 | | | abnormal | | | | | | |
| | | | discharge traces | | | | | | |
| Comparative | None | 10 min | abnormal | 15776 | present | 25 | 19 | remaining | 0.01 |
| Example 5 | | | discharge traces | | | | | | |
| Comparative | cutout | Stopped | signigficant | | present | could not obtain a measurable film | | | |
| Example 6 | occurred | after 3 | abnormal | | | | | | |
| | | min | discharge traces | | | | | | |
| Comparative | None | Stopped | signigficant | | present | could not obtain a measurable film | | | |
| Example 7 | | after 5 | abnormal | | | | | | |
| | | min | discharge traces | | | | | | |
| Comparative | None | 10 min | abnormal | 1219 | present | 40 | 22 | remaining | 0.04 |
| Example 8 | | | discharge traces | | | | | | |
| Comparative | cutout | Stopped | signigficant | | present | could not obtain a measurable film | | | |
| Example | chipping | after 1 | abnormal | | | | | | |
| | | min | discharge traces | | | | | | |
| Comparative | chipping | 10 min | abnormal | 3684 | present | 25 | 18 | remaining | 0.05 |
| Example | | | discharge traces | | | | | | |

### [Evaluation]

With respect to the sputtering targets of Examples 1 to 14 and Comparative Examples 1 to 10, the presence or absence in chipping of the target was recorded at the time of cutting machining, and furthermore, the pieces of the sintered body for analysis were performed an oxygen concentration analysis at non-dispersive infrared-absorbing method. In addition, the theoretical density ratio of the sintered bodies was calculated in the method described above. Also, the deflective strength was tested in three-point bending test at a deformation rate of 0.5 mm/min to comply with JIS R1601. Furthermore, the target surface in 100 cm² after machining was observed, and the number of Na compound aggregates having 0.05 mm² or more was measured, and an average value per its 1 cm² area was calculated. The average grain size of the Na compound phase and the average grain size of the metal phase were measured by the above method. Also, the content of the Ga and Na in the produced sputtering targets was carried out the quantitative analysis using ICP method (inductively coupled plasma method). In addition, the targets were left at 25° C. in a humidity of 60% for 8 hours, and discoloration of the surface thereof was visually checked.

Furthermore, the sputtering targets were set in a magnetron sputtering apparatus, a film having 1000 nm of thickness was deposited on a silicon substrate with an oxide film by an input power: a pulsed DC sputtering of 8 W/cm². Also, Ar pressure during sputtering was set to 1.3 Pa, the distance between the sputtering target and the substrate was set to 70 mm. In addition, heating of the substrate was not performed at the time of deposition. Moreover, in the above conditions, continuous sputtering for 10 minutes was carried out, and the number of occurrences of micro-arc abnormal discharge was automatically recorded by arcing counter provided in the sputtering power source. Also, the number of occurrences of significant abnormal discharge was visually checked. In the sputtering targets of the Comparative examples, since significant abnormal discharge occurred, plasma was lost, and the phenomenon in which sputtering cannot be performed occurred, the time elapsed until plasma loss or stop of sputtering was defined as the time of continuous sputtering.

The check of whether significant abnormal discharge traces such as melting, cavity and chipping of the sputtering target surface after sputtering are present or not was carried out.

The film obtained by the above sputtering was peeled, and the quantitative measure of Na, Ga, and In in the film was carried out by using the ICP method.

For these evaluations, the results for the sputtering targets each of the Examples and the sputtering targets of each of the comparative examples described above were shown in Tables 2 and 3, and Tables 5 and 6.

As can be seen from these evaluation results, spots or color unevenness occurred in every sputtering target of the Comparative Examples as shown in Table 5; whereas any development of spots and color unevenness did not occur and there was no surface discoloration in the sputtering targets of the Examples as shown in Table 2.

Moreover, neither cracking nor chipping occurred during cutting machining in the sputtering target of the Examples as shown in Table 3; whereas chipping did occur at the time of cutting machining in the sputtering target of the Comparative Examples 1, 6 and 9 as shown in Table 6. In addition, in the sputtering target of the Comparative Examples 4, 6, and 9, since the metal phase of the crystal grains is increased, cutout or/and chipping occurred.

Furthermore, the number of times of the micro-arc abnormal discharge during sputtering in every sputtering target of the Examples as shown in Table 3 was less than 1000 times; whereas the number of times thereof in every sputtering target of the Comparative Examples exceeded 1000 times and was frequent.

Moreover, the number of times of significant abnormal discharge during sputtering in every sputtering target of the Examples as shown in Table 3 was zero times; whereas the number of times thereof in every sputtering target of the Comparative Examples was once or more and were frequent.

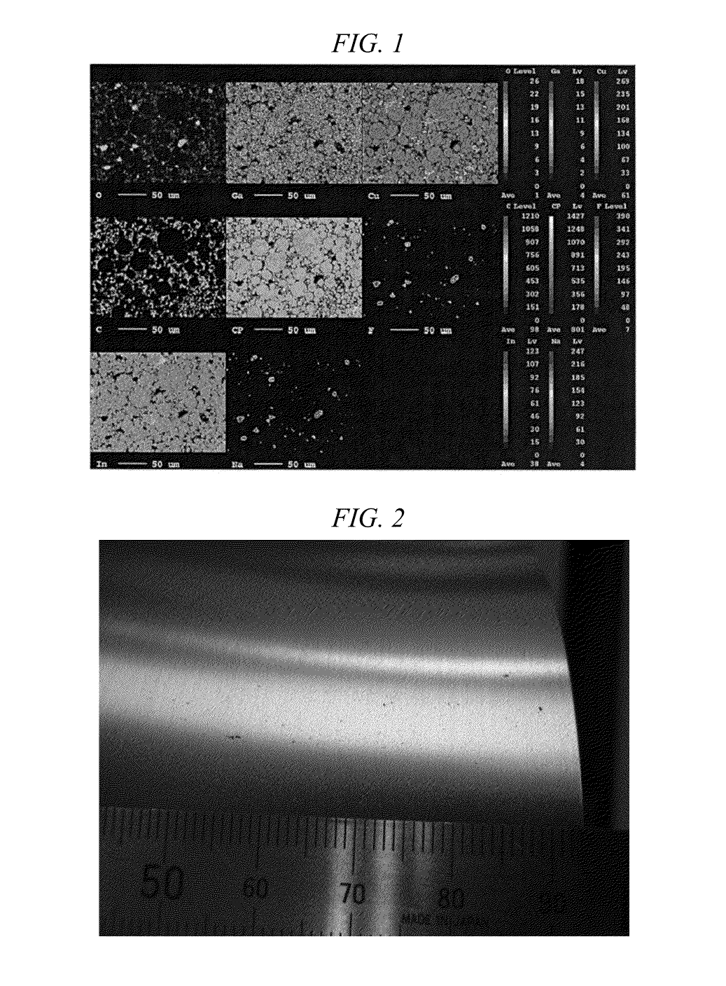

Here, with respect to the sputtering target of Example 1, as a typical example of the element distribution mapping images by electron probe microanalysis (EPMA) is shown in FIG. 1. In addition, although every image of the EPMA is a color image in original image, the images are described by converting in black and white image by using a gray scale, and when the brightness is high, the content of the measurement element tends to be high. From these images, it can be confirmed that the sputtering target of each present example has a composition in which the Na compound phase is dispersed in the sputtering target material.

In addition, in order to use the present invention as a sputtering target, the sputtering target preferably has a surface roughness: 5 μm or less, and metallic impurity concentration: 0.1 at. % or less. The sputtering targets of each example described above have satisfied these conditions.

The technical scope of the present invention is not limited to the above described embodiment and the above examples, but it can include various changes made to the above invention without departing from the spirit thereof.

### FIELD OF INDUSTRIAL APPLICATION

According to a sputtering target related to the present invention and a producing method thereof, the sputtering target contains Ga: 2 to 30 at. %, In: 15 to 45 at. %, Na: 0.05 to 15 at. % as metal components other than F, S and Se, and the remainder composed of Cu and inevitable impurities, and in the sputtering target material, it has a composition in which a Na compound phase is dispersed and an average grain size of the Na compound phase is 10 μm or less. Therefore, discoloration of the sputtering target caused by moisture adsorption and abnormal discharge during sputtering is suppressed even though Na is contained, and furthermore, the sputtering target has a high strength and is hard to crack. Thus, the present invention has a high mass-productivity, can achieve the addition of Na to the light adsorbing layer, and can produce a solar battery having a high power generation efficiency by depositing a light adsorbing layer of a CIGS-thin-film-type-solar battery by sputtering using the sputtering target of the present invention.

1. A sputtering target is a sintered body having a component composition containing Ga: 2 to 30 at. %, In: 15 to 45 at. %, Na: 0.05 to 15 at. %, and the remainder composed of Cu and inevitable impurities,
wherein the sintered body having a composition in which a Na compound phase is dispersed and the Na is contained in the Na compound phase in a state of a Na compound formed of at least one form of sodium fluoride, sodium sulfide, and sodium selenide, and
wherein an average grain size of the Na compound phase is 10 μm or less.

2. The sputtering target according to claim 1, wherein
a theoretical density ratio of the sintered body is 90% or more,
a deflective strength is 60 N/mm² or more,
a bulk resistivity being 0.1 Ω*cm or less, and
the number of Na compound aggregates having a size of 0.05 mm² or more contained in an area of 1 cm² of a surface of the sputtering target is one or less on average.

3. The sputtering target according to claim 1, wherein
the content of oxygen of the sintered body is 50 to 2000 ppm.

4. The sputtering target according to claim 1, wherein
an average grain size of the metallic phase in the sputtering-target material is 50 μm or less.

5. A producing method of a sputtering target comprises a step of:
sintering a mixed powder of a powder containing Cu, Ga, and In and a Na compound powder to produce a sintered body containing Cu, Ga, In, and Na,
wherein the powder containing Cu, Ga, and In is made of either one of: a binary or ternary alloy powder selected from the group consisting of Cu, Ga, and In; and a binary or ternary alloy powder selected from the group consisting of Cu, Ga, and In and a Cu powder, and
an average particle size of the mixed powder is 1 to 70 μm.

6. The producing method of the sputtering target according to claim 5, wherein
the Na compound powder and the powder containing Cu, Ga, and In are mixed by dry blending method.

7. The producing method of the sputtering target according to claim 5, wherein
the method comprises either one of the steps of:
drying the Na compound powder at a temperature of 70° C. or more before the mixed powder is prepared; and drying the mixed powder at a temperature of 70° C. or more before sintering the mixed powder.

8. The producing method of the sputtering target according to claim 5, wherein
sintering of the mixed powder is performed in a non-oxidizing atmosphere or vacuum in the step of sintering.
